(19) United States
(12) Patent Application Publication
(10) Pub. No.: US 2004/0217424 A1
(43) Pub. Date: Nov. 4, 2004

(54) Semiconductor device structure facilitating electrostatic discharge protection and manufacturing method thereof

(75) Inventor: An Shih, Changhua (TW)

Correspondence Address: LIU & LIU LLP, 811 WEST SEVENTH STREET, SUITE 1100, LOS ANGELES, CA, 90017, US

(73) Assignee: Toppoly Optoelectronics Corp.

(21) Appl. No.: 10/837,263

(22) Filed: Apr. 30, 2004

(30) Foreign Application Priority Data
May 2, 2003 (TW) 92112088

(51) Int. Cl. H01L 23/62

(52) U.S. Cl. 257/355; 257/356

(57) ABSTRACT

A structure of a semiconductor device facilitating electrostatic discharge protection at least includes a source terminal, a drain terminal, and a gate terminal, wherein a portion of the source terminal and a portion of the drain terminal are overlapped above the gate terminal to increase the coupling capacitance so that the electrostatic discharge protection device can be turned on quickly. Accordingly the response of the electrostatic discharge protection device to an electrostatic discharge can be effectively promoted.

### CROSS-REFERENCE TO RELATED APPLICATION

This application claims the priority benefit of Taiwan application serial no. 92112088, filed on May 2, 2003.

### BACKGROUND OF THE INVENTION

1. Field of the Invention

This invention generally relates to electrostatic discharge (“ESD”) protection structure in semiconductor devices, and more particularly to semiconductor devices having an improved electrostatic discharge protection structure.

2. Description of Related Art

As the control circuits and the driver circuits are fabricated directly on flat panel displays (e.g., Liquid Crystal Display (“LCD”) panels), those integrated circuits, like CMOS ICs, face a common problem—damage due to electrostatic discharge. Especially, in the situation where thin film transistor (TFT) devices are fabricated on an insulated glass substrate, at the instant (around 10 ns) the electrostatic discharge occurs, the heat generated by the electrostatic discharge cannot be dissipated immediately due to the insulation of the glass substrate, which is inclined to damage those TFT devices. If any control IC or driver IC on the glass substrate is damaged due to the electrostatic discharge, even if the pixels are intact, the LCD panel does not work. Hence, if the control circuits and the driver circuits are manufactured on the LCD panel, electrostatic discharge protection for TFT devices become more and more important.

FIG. 1 is a top view of a conventional electrostatic discharge protection structure in a top gate low temperature polysilicon (“LTPS”) TFT panel. In this structure, the polysilicon-island formed by excimer laser annealing (“ELA”) process can be used as a channel 112. Polysilicon on the two sides of the channel 112 after ion implantation become a source region 108 and a drain region 110. Gate terminal 102 is set above the channel 112. Source metal 104 and drain metal 106 are electrically connected to source region 108 and drain region 110 through vias 114 and 116 respectively. It should be noted that there are a gate insulator between gate terminal 102 and a channel 112, and inter-layer dielectric layers between the source metal 104/source region 108 and the drain metal 106/drain region 110. For simplification, the gate insulator and inter-layer dielectric layers are not shown in FIG. 1.

Referring to FIG. 1, the gate terminal 102 of the top gate LTPS thin film transistor is used as a mask to be a self-alignment structure, so that the source region 108 and the drain regions 110 align with the two sides of the gate terminal 102, but do not overlap the gate terminal 102.

When electrostatic charges enter the structure shown in FIG. 1, they turn on the MOS diode in the TFT by coupling the drain to the gate and then the TFT releases those charges. However, the coupling capacitances between gate and drain, and between gate and source, are limited. Hence, it takes longer time to turn on the MOS diode and to release those electrostatic charges. Such design cannot effectively protect the devices from ESD damage to some extent.

### SUMMARY OF THE INVENTION

The present invention provides a semiconductor device (e.g., TFT) structure that accelerates the turn-on speed for electrostatic discharge protection so that the electrostatic discharges can be released quickly, thereby effectively protecting the device from ESD damage. Accordingly the response of the electrostatic discharge protection device to an electrostatic discharge can be effectively promoted.

The present invention provides a semiconductor device structure comprising a source terminal, a drain terminal, and a gate terminal, wherein a portion of the drain terminal are overlapped above the gate terminal.

In an embodiment of the present invention, the drain terminal further includes a drain region and a drain metal, and the source terminal further includes a source region and a source metal; the electrostatic discharge protection device further comprises a channel, a gate insulator, and an inter-layer dielectric layer. The channel is formed on a substrate. The drain region and the source region are formed on the two sides of the channel respectively. The gate insulator is formed on the channel and the gate terminal is formed on the gate insulator. The inter-layer dielectric layer is formed on the substrate and covers the gate terminal, the drain region, and the source region. The drain metal is formed on the inter-layer dielectric layer and is connected to the drain region via a drain contact window in the inter-layer dielectric layer. The source metal is formed on the inter-layer dielectric layer and is connected to the source region via a source contact window in the inter-layer dielectric layer. The source metal and the drain metal are insulated by the inter-layer dielectric layer with a portion of the drain metal overlapped above the gate terminal.

The present invention also provides a method of fabricating an electrostatic discharge protection device including forming a source terminal, a drain terminal and a gate terminal, wherein a portion of the drain terminal overlap above the gate terminal.

In an embodiment of the present invention, the drain terminal further includes a drain region and a drain metal, and the source terminal further includes a source region and a source metal. The method further comprises the steps of forming a polysilicon-island layer on a substrate; forming a gate insulator on the polysilicon-island layer; forming the gate terminal on the a gate insulator; forming the drain region and the source region on the two sides of the polysilicon-island layer respectively; forming an inter-layer dielectric layer on the substrate to cover the gate terminal, the drain region, and the source region; forming a drain contact window and a source contact window on the inter-layer dielectric layer to expose the surface of the drain region and the source region; forming the source metal on the inter-layer dielectric layer and the source contact window and forming the drain metal on the inter-layer dielectric layer and the drain contact window; wherein the source metal and the drain metal are insulated by the inter-layer dielectric layer with the gate terminal and a portion of drain metal overlapped above the gate terminal.

Accordingly, because the source metal and the drain metal are insulated by the inter-layer dielectric layer with a portion of the drain metal overlapped above the gate terminal, the coupling capacitance Cgd is higher than the conventional one, which accelerates turning on the MOS diode to release the electrostatic charges quickly thereby protecting the devices from ESD damage.

Furthermore, the electrostatic discharge protection device of the present invention is fabricated with the same process as control ICs and driver ICs. The fabricating process of the present invention only requires slight modification of the mask for defining the source metal and drain metal; i.e., no additional mask is required. Hence, the process of fabricating the electrostatic discharge protection device is totally compatible with existing processes.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF THE DRAWINGS

FIG. 1 is a top view of a conventional electrostatic discharge protection device in a top gate low temperature polysilicon (“LTPS”) thin film transistor panel.

FIG. 2 is a simplified circuit providing electrostatic discharge protection to the semiconductor device shown in FIG. 3.

FIG. 3 a top view of a semiconductor device structure facilitating electrostatic discharge protection in accordance with an embodiment of the present invention.

FIG. 4 is a cross sectional view taken along the line A-A in FIG. 3.

FIG. 5 is a schematic representation of an electronic device having a display device incorporating the semiconductor device of FIG. 3 and ESD protection circuit of FIG. 2.

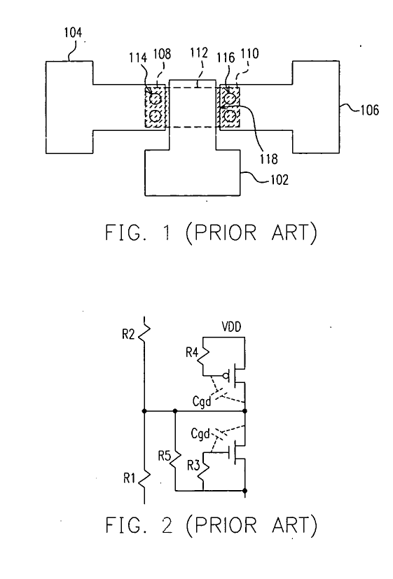

### DESCRIPTION OF THE EMBODIMENTS

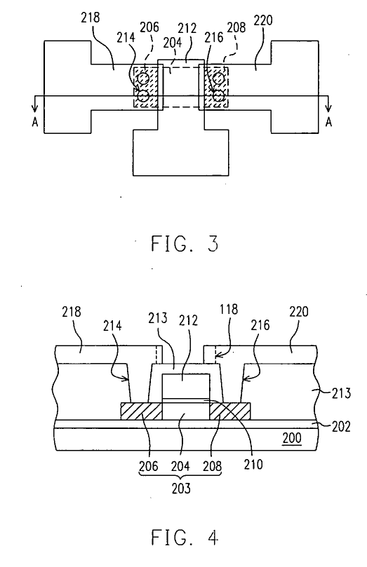

Referring to FIGS. 3 and 4, FIG. 3 a top view of a structure of a semiconductor device facilitating electrostatic discharge protection in accordance with an embodiment of the present invention, and FIG. 4 is the cross sectional view taken along the line along A-A shown in FIG. 3. A method of fabricating a structure of a semiconductor device facilitating electrostatic discharge protection of the present invention is described as follows. First, a substrate 200 is provided. In an embodiment of the present invention, the substrate 200 is a glass substrate. Then a buffer layer 202 is formed on the substrate 200, wherein the material of the buffer layer 202 is silicon nitride, for example. The purpose of the buffer layer 202 is to prevent the impunity (e.g., Na+) from diffusing into the subsequently formed semiconductor device.

Then, a polysilicon-island layer 203 is formed on the buffer layer 202. The ploysilicon-island layer 203 is formed by performing an excimer laser annealing (“ELA”) process, and can be used as a channel 204. Furthermore, the ploysilicon-island layer 202 will be doped as the drain region 208 and the source region 206 of the thin film transistor.

Then, a gate insulator 210 and a gate terminal 212 are formed on substrate 200. In this embodiment, the gate insulator 210 and the gate terminal 212 can be formed by forming a insulating layer (not separately shown in the figures) and a conducting layer (not separately shown in the figures) in sequence and patterning the insulating layer and the conducting layer to form the gate insulator 210 and the gate terminal 212. The material of the gate terminal 212 can be Cr, W, Ta, Ti, Mo, Al, or other alloys.

An inter-layer dielectric layer 213 is then formed on the substrate 200. The material of the inter-layer dielectric layer 213 is silicon dioxide or silicon nitride, for example. Then, vias 214 and 216 are formed in the inter-layer dielectric layer 213 to expose the surface of the source region 206 and the drain region 208 respectively.

A metal layer (not separately shown in the figures) is then formed on the inter-layer dielectric layer 213 to fill up the vias 214 and 216. The metal layer is patterned to form the drain metal 220 and the source metal 218 and electrically connected to the drain region 208 and the source region 206 respectively. In this embodiment, the drain terminal comprises the drain metal 220 and the drain region 208; the source terminal comprises the source metal 218 and the source region 206. Furthermore, the source metal 218 and the drain metal 220 are insulated by the inter-layer dielectric layer 213 with the gate terminal 212 and the drain metal 220 overlap above the gate terminal 212 at the edge 118 of the drain metal 220 (as shown in FIG. 4).

FIG. 2 is a simplified ESD protection circuit coupling the semiconductor structures to be protected, (such as the LTPS-TFT shown in FIGS. 3 and 4) in a CMOS TFT configuration. When the electrostatic charges enter into the circuit, they turn on the MOS diode (NMOS and/or or PMOS) in the TFT by coupling the drain terminal to the gate terminal and then the MOS diode releases those charges from the circuit. In this embodiment of the present invention, because the source metal 218 and the drain metal 220 are insulated by the inter-layer dielectric layer 213 with and overlapped above a portion of the gate terminal 212, the coupling capacitance Cgd is higher than the conventional one, which accelerates turning on of the MOS diode in the TFT to release the electrostatic charges quickly thereby protecting the devices from ESD damage.

Furthermore, the structure of the semiconductor device of the present invention is fabricated with the same process as other components, such as in the case of a display panel, the control ICs and the driver ICs for the display panel. The method of the present invention only requires slight modification of the mask for defining the source metal and drain metal; i.e., no additional mask is required. Hence, the process of fabricating the structure of a semiconductor device is totally compatible with existing processes.

Referring to FIG. 4, the structure of the semiconductor device facilitating electrostatic discharge protection in accordance with an embodiment of the present invention is formed at a non-display area to connect the signal source and the display area. It includes a channel 204, a source region 206, a drain region 208, a gate insulator 210, a gate terminal 212, an inter-layer dielectric layer 213, a source metal 218 and a drain metal 220.

The channel 204 is formed on the substrate 200. The drain region 208 and the source region 206 are set on the two sides of the channel 204 respectively.

The gate insulator 210 is formed on the channel 204. The gate terminal 212 is formed on the gate insulator 210.

The inter-layer dielectric layer 213 is formed on the substrate 200 and covers the gate terminal 212, the drain region 208, and the source region 206. The drain metal 220 is formed on the inter-layer dielectric layer 213 and is electrically connected to the drain region 208 via a drain contact window 216 in the inter-layer dielectric layer 213; the source metal 218 is formed on the inter-layer dielectric layer 213 and is electrically connected to the source region 206 via a source contact window 214 in the inter-layer dielectric layer 213. In this embodiment, the source metal 218 and the drain metal 220 are insulated by the inter-layer dielectric layer 213 with the gate terminal 212 and the drain metal 220 overlapped above a portion of the gate terminal 212.

Furthermore, in an embodiment of the present invention, a buffer layer 202 can be set between the substrate 200 and the channel 204, the source region 206, the drain source 208 and the inter-layer dielectric layer 213. The purpose of the buffer layer 202 is to prevent the impurity from diffusing into the semiconductor device.

In the embodiments described above, the present invention can be applied to the top gate LTPS TFT panel. However, the present invention also can be applied to the bottom gate TFT panel; the semiconductor device can be fabricated by forming on a substrate a gate, a gate insulator, a channel, a drain region, and a source region; setting the electrostatic discharge protection device on the panel between the display area and the signal source; defining the drain region to overlap a portion of them above the gate in order to increase the coupling capacitance between the gate and the drain, thereby accelerate the turn-on speed of the electrostatic discharge protection device.

Accordingly, the structure of the semiconductor device having a structure for facilitating electrostatic discharge protection can be formed without any special limitation. If the structure of the semiconductor device includes a source terminal, a drain terminal and a gate terminal, and a portion of the drain terminal are overlapped above the gate terminal, then this is covered within the scope of the present invention.

In the embodiments described above, the coupling capacitance of Cgd can be effectively increased and thereby accelerate the turn-on speed of the electrostatic discharge protection device.

Accordingly, the present invention present invention has the following characteristics:

Because the source metal and the drain metal are insulated by the inter-layer dielectric layer with and the drain metal overlapped above the gate terminal, the coupling capacitance Cgd is higher than the conventional one, which accelerates turning on the MOS diode to release the electrostatic charges quickly thereby protecting the devices from ESD damage.

Furthermore, the structure of a semiconductor device facilitating electrostatic discharge protection of the present invention can be fabricated using the same process as the control ICs and the driver ICs. The fabrication method of the present invention only requires slight modification of the mask defining the source metal and drain metal; i.e., no additional mask is required. Hence, the process is totally compatible with the existing processes.

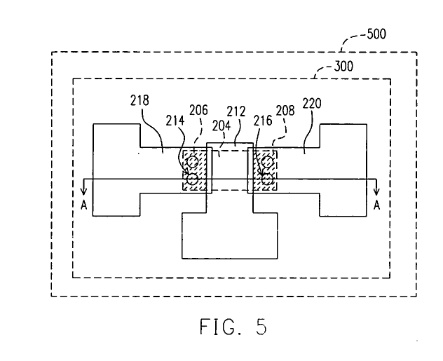

It should be noted that the present invention can also be applied in an electronic device 500 comprising semiconductor device 300 of FIG. 3 such as a display panel including active matrix LCD, OLED, etc. and the electrostatic discharge protection device of FIG. 2 (not shown in FIG. 5) to effectively increase the coupling capacitance of Cgd as shown in FIG. 5. Accordingly, a highly quality and reliable display panel for electronic devices can be constructed.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A semiconductor device having a structure that facilitates electrostatic discharge protection, said device comprising a source terminal, a drain terminal, and a gate terminal, wherein a portion of said drain terminal overlaps said gate terminal.

2. The semiconductor device of claim 1, wherein said drain terminal further includes a drain region and a drain metal, and said source terminal further includes a source region and a source metal.

3. The semiconductor device of claim 2, further comprising:
a channel formed on a substrate, wherein said drain region and said source region are disposed on two sides of said channel respectively;
a gate insulator formed on said channel, wherein said gate terminal is disposed on said gate insulator; and
an inter-layer dielectric layer formed on said substrate and covering said gate terminal, wherein said drain region, said source region and said drain metal are disposed on said inter-layer dielectric layer and connected to said drain region via a drain contact window in said inter-layer dielectric layer; and wherein said source metal is disposed on said inter-layer dielectric layer and connected to said source region via a source contact window in said inter-layer dielectric layer;
wherein said source metal and said drain metal are insulated by said inter-layer dielectric layer and said drain metal overlap said gate terminal.

4. A display panel having a structure capable of facilitating an electrostatic discharge protection, said device comprising a source terminal, a drain terminal, and a gate terminal, wherein said drain terminal overlaps said gate terminal.

5. The display panel of claim 4, wherein said drain terminal further includes a drain region and a drain metal, and said source terminal further includes a source region and a source metal.

6. The display panel of claim 5, further comprising:
a channel formed on a substrate, wherein said drain region and said source region are disposed on two sides of said channel respectively;
a gate insulator formed on said channel, wherein said gate terminal is disposed on said gate insulator; and
an inter-layer dielectric layer formed on said substrate and covering said gate terminal, wherein said drain region, said source region and said drain metal are disposed on said inter-layer dielectric layer and connected to said drain region via a drain contact window in said inter-layer dielectric layer; and wherein said source metal is disposed on said inter-layer dielectric layer and connected to said source region via a source contact window in said inter-layer dielectric layer;
wherein said source metal and said drain metal are insulated by said inter-layer dielectric layer and said drain metal overlap said gate terminal.

7. An electronic device comprising a display panel having a structure capable of facilitating an electrostatic discharge protection, said device comprising a source terminal, a drain terminal, and a gate terminal, wherein said drain terminal overlaps said gate terminal.

8. The structure of an electronic device of claim 7, wherein said drain terminal further includes a drain region and a drain metal, and said source terminal further includes a source region and a source metal.

9. The structure of an electronic device of claim 8, further comprising:
a channel formed on a substrate, wherein said drain region and said source region are disposed on two sides of said channel respectively;
a gate insulator formed on said channel, wherein said gate terminal is disposed on said gate insulator; and
an inter-layer dielectric layer formed on said substrate and covering said gate terminal, wherein said drain region, said source region and said drain metal are disposed on said inter-layer dielectric layer and connected to said drain region via a drain contact window in said inter-layer dielectric layer; and wherein said source metal is disposed on said inter-layer dielectric layer and connected to said source region via a source contact window in said inter-layer dielectric layer;
wherein said source metal and said drain metal are insulated by said inter-layer dielectric layer and said drain metal overlap said gate terminal.

10. A method of fabricating a semiconductor device that facilitates electrostatic discharge protection, said method comprising forming a source terminal, a drain terminal, and a gate terminal, wherein at least one of a portion of said drain terminal and said source terminal overlaps said gate terminal.

11. The method of fabricating a semiconductor device of claim 10, wherein said drain terminal further includes a drain region and a drain metal, and said source terminal further includes a source region and a source metal.

12. The method of fabricating a semiconductor device of claim 7, wherein the step of forming said gate terminal, said drain terminal, and said source terminal further comprises:
forming a polysilicon layer on a substrate;
forming a gate insulator on said poly-island layer;
forming said gate terminal on said a gate insulator;
forming said drain region and said source region on the two sides of said poly-island layer respectively;
forming an inter-layer dielectric layer on said substrate to cover said gate terminal, said drain region, and said drain region;
forming a drain contact window and a source contact window on said inter-layer dielectric layer to expose the surface of said drain region and said source region;
forming said source metal on said inter-layer dielectric layer and said source contact window and forming said drain metal on said inter-layer dielectric layer and said drain contact window;
wherein said source metal and said drain metal are insulated by said inter-layer dielectric layer and said drain metal overlap said gate terminal.

13. The method of fabricating a semiconductor device of claim 11, further comprising a step of doping said polysilicon layer by using said gate terminal as a mask.

14. The method of fabricating a semiconductor device of claim 11, wherein the step of forming said source metal and said drain metal further comprises the steps of:
forming a metal layer on said source contact window, said drain contact window and said inter-layer dielectric layer; and
patterning said metal layer to form said source metal and said drain metal.
